(19) United States
(12) Patent Application Publication
(10) Pub. No.: US 2005/0087392 A1
(43) Pub. Date: Apr. 28, 2005

(54) Loudspeaker enclosure

(76) Inventors: Andrew E. Flanders, Cornelius, OR (US); Bradley E. Judah, Cornelius, OR (US); Andrew Bartha, Gaston, OR (US)

Correspondence Address: JONES, TULLAR & COOPER, P.C., P.O. BOX 2266 EADS STATION, ARLINGTON, VA, 22202, US

(21) Appl. No.: 10/939,112

(22) Filed: Sep. 13, 2004

Related U.S. Application Data
(60) Provisional application No. 60/502,199, filed on Sep. 12, 2003.

(51) Int. Cl. A47B 81/06; H05K 5/00

(52) U.S. Cl. 181/156; 181/199

(57) ABSTRACT

A loudspeaker enclosure is arranged to support at least one electromagnetic loudspeaker driver generating both front and back acoustic waves. The front of the speaker is substantially planar and the driver is mounted in an opening in the front of the enclosure to radiate forwardly. The driver's back wave communicates through a passage adapted to function as an impedance-matched transmission line cavity having a length that is, preferably, three times the driver cone's diameter, and having one or more ports terminating in openings defined in a plane that is, preferably, substantially perpendicular to the enclosure's planar front. The port or ports have a cross sectional area of, preferably 0.707 to 1.414 times the operative area of the driver cone, thereby giving a highly efficient means of sound propagation.

### CROSS REFERENCE TO RELATED APPLICATIONS

This application claims the benefit of priority under 35 U.S.C. 119(e) of U.S. Application No. 60/502,199, which was filed on Sep. 12, 2003, the entire disclosure of which is incorporated herein by reference.

### BACKGROUND OF THE INVENTION

1. Field of the Invention

The present invention relates in general to loudspeakers for sound reproduction or sound reinforcement, and methods of building acoustically efficient enclosures for loudspeakers that permit high accuracy reproduction.

2. Description of the Background Art

Loudspeaker enclosures of the prior art generally include a front opening adapted to receive a loudspeaker driver for directing the front acoustic wave of a loudspeaker forwardly into a room or other space. Prior art enclosures are often categorized in one of two large groups, namely sealed boxes or vented boxes.

Sealed box or infinite baffle loudspeaker enclosures customarily include a selected quantity of damping material in the interior volume and provide a damped air-spring like effect which, in theory, provided more precise driver excursion control, but at a cost of somewhat diminished efficiency, so that a typical loudspeaker receiving an electrical music signal power level of one watt (1 W) might generate, during playback, an acoustic power level or loudness of eighty five decibels (85 dB).

In order to increase perceived playback loudness or efficiency, many loudspeaker developers used vented boxes, typically having one or more resonant or tuned vent tubes. The tuned vent structures were typically dimensioned to permit a maximum driver excursion at a selected frequency, thereby maximizing perceived loudness, so that a typical vented loudspeaker receiving an electrical music signal power level of one watt (1 W) might generate, during playback, an acoustic power level of ninety-five decibels (95 dB) or more, thereby providing what some thought to be an important marketing advantage over the less efficient sealed box designs. Vented enclosure tuned ports of the prior art usually direct the back acoustic wave of the loudspeaker into free space in the direction either (1) opposite or (2) parallel to the front wave. Both forms of enclosure contribute to sound which may be characterized as less than desirable in bass reproduction, fidelity and liveliness. These deficiencies are characterized as weak bass, cabinet cavity formants and over-damped sound which is “dry” or lifeless in character. Typical prior art enclosures are disclosed in U.S. Pat. Nos. 2,206,427; 2,815,086; 2,822,884; 2,866,513; 2,871,972; 3,500,953; 3,529,691; and 3,892,288.

Both the sealed box loudspeakers and the vented box loudspeakers essentially reflect the driver's back wave within the box, causing undesirable non-linear standing wave effects.

In response, high efficiency transmission line loudspeaker enclosures were proposed, such as are disclosed in U.S. Pat. No. 4,593,784 and No. 4,753,317. For purposes of demonstrating the skill of persons in the art, the entire disclosures of all of the above cited references are incorporated herein by reference. Prior art transmission line enclosures are complicated and have serpentine-like long acoustic paths often filled with damping material. These enclosure structures, when combined with an electromagnetic driver producing both front and back acoustic waves, provide reduced inter-modulation (IM) distortion and improved fidelity. The serpentine-path enclosure of traditional transmission line-loaded loudspeaker is difficult and expensive to build, since an internal serpentine labyrinth is required. This complicated internal structure limits the possibilities for aesthetic design flexibility and mandates a large, heavy and deep cabinet having an unconventional external appearance with abysmally low wife acceptance factor.

In view of the foregoing, there is a need for a loudspeaker enclosure providing much greater aesthetic design flexibility with an external appearance more in keeping with traditional tastes, that can be produced in reasonable sizes and at a more reasonable cost.

### SUMMARY OF THE INVENTION

An object of this invention to provide a loudspeaker enclosure which overcomes the limitations of prior loudspeaker enclosures.

Another object of this invention is the provision of a loudspeaker enclosure in which the back wave port has a characteristic acoustic impedance which substantially matches the acoustic characteristic impedance of the electromagnetic driver, thereby coupling the back wave acoustic energy into a room with high efficiency.

Still another object of this invention is to provide a loudspeaker enclosure in which the back wave port is configured to back load the electromagnetic driver in a balanced, substantially reflectionless manner with respect to the front load, to achieve significantly improved fidelity, extended bandwidth, high and low, and substantially maximized efficiency with superior energy transfer.

Another object of this invention is the provision of a loudspeaker enclosure in which the back wave port is dimensioned to pass a wide band of audio frequencies, i.e. several octaves, without inducing a standing wave or resonance in the transmission line path between the driver and the port.

A further object of this invention is to provide a loudspeaker enclosure of the class described in which the back wave port terminates an acoustic transmission line substantially in its acoustic characteristic impedance, thereby providing a flat response over the band pass and preclude the prior art's extensive use of dampening material (to absorb internal standing waves). It is such dampening materials that function to muffle the sound and prevent the broadcasting of sound that is live in character.

A still further object of this invention is the provision of a loudspeaker enclosure of the class described in which the back wave port functions to load the enclosure cavity over a wide band, to avoid resonant peaks or valleys which otherwise “color” the sound.

Another object of this invention is to provide a loudspeaker enclosure of the class described in which the back wave port is configured with a lip by which to introduce turbulent air flow at very low frequencies, thereby separating further the front and back acoustic waves and correspondingly extend the bass response.

Still another object of this invention is the provision of a loudspeaker enclosure of the class described which may be utilized with frequency selective reflectors to produce increased dimension and motion to the sound with frequency.

A still further object of this invention is to provide a loudspeaker enclosure of the class described which is of simplified construction for economical manufacture.

The aforesaid objects are achieved individually and in combination, and it is not intended that the present invention be construed as requiring two or more of the objects to be combined.

In its basic concept, the loudspeaker enclosure of this invention provides a back wave port disposed in a plane substantially perpendicular or opposite to the plane of the front wave opening and having an area 0.5 to 2.0 times the operative area of the associated electromagnetic driver, the back side of the associated driver communicating a back wave to the back wave port through a cavity that functions in the manner of an acoustic transmission line and an acoustic impedance matching acoustic transformer.

A loudspeaker enclosure is arranged to support at least one electromagnetic loudspeaker driver generating both front and back acoustic waves. The front of the speaker is substantially planar and the driver is mounted in an opening in the front of the enclosure to radiate forwardly. The driver 's back wave communicates through a passage adapted to function as an impedance-matched transmission line cavity having a length that is, preferably three times the driver cone's diameter, and having one or more ports terminating in openings defined in a plane that is, preferably, substantially perpendicular to the enclosure's planar front. The port or ports have a cross sectional area of 0.5 to about 2.0 times the operative area of the driver cone of the loudspeaker (preferably 0.707 to 1.414 times the operative area of the driver cone), thereby giving a highly efficient means of sound propagation.

The enclosure may also support optional high frequency “tweeter” speakers, which provide one or more planes of sound propagation depending on the usage environment. The architecture of the internal speaker box design provides various reflectors and deflectors to provide the most direct path of sound egress and minimize resonant standing waves or sound cancellation effects associated with the opposite polarity of the back acoustic waves derived from the speaker. The resultant transmission path and port opening for the back acoustic waves minimizes acoustic cancellation between the front and back acoustic waves while simultaneously facilitating the maximum possible propagation of acoustic energy derived from the speaker by virtue of the matching to the characteristic acoustic impedance of the driver at the port(s).

In accordance with the method of the present invention, the acoustical characteristic impedance of the driver is “matched” to the acoustical impedance of the enclosure such that the enclosure does not resonate, and so provides maximum sound propagation without causing a harmful phase shift to harmonics as in the prior art's more resonant enclosures. And to further allow energy to transfer efficiently and in order for the acoustic back wave to not cancel any of the front wave the back wave propagates at greater than 90 degrees from the vector angle of the front wave propagation. In order to provide some physical understanding of this process of “matching”, we first observe that:
Sound Intensity/=is defined as p²/ρc, (1)
where p=Sound Pressure Level (SPL),
and where Acoustical Characteristic Impedance=ρc
and where ρ=density of Air (g/cm³),
c=constant velocity for sound (cm/sec)

This means that the dimensional units of Acoustical Characteristic Impedance, ρc, are expressed as: (g/cm²)(sec).

When examining Acoustical Impedance, the mass (g) is ever present for the medium (Air) that the sound is propagating within. So, within the enclosure, the variable available to the designer is “Area”, since sound moves at a constant velocity. “Area”, as used in the method of the present invention, is the cross sectional area of the transmission line path that the driver's back wave or pressure wave travels along to exit the enclosure.

From a hypothetical Electrical Power application which can be analogously applied to acoustic power application, one can follow the rule that the most efficient (maximum) transfer of power occurs within the limits of √2 and 1/√2, meaning that when a first network's impedance is a multiple of √2 and 1/√2 times a second network's impedance, then the impedances are deemed to be matched, and so signal reflections and standing waves are likely to be acceptably low.

In the method of the present invention, Area is determined to be the variable, and so for the most efficient transfer of acoustical power, the area of the transmission line should at all times fall within √2×Cross-sectional area of the driver cone and 1/√2×Cross-sectional Area of the diver cone. I.E. Between 0.707A_{DC} and 1.414A_{DC}, where A_{DC}=Effective cross-sectional area of the driver cone.

Further, in order for the driver to recognize its characteristic impedance within the enclosure, the length of the transmission line path must be sufficient. This has been empirically determined by the inventors to be equal to or greater than 2.5 times to 3 times the active diameter of the driver cone (with 2.5 times the driver cone diameter giving the minimum acceptable efficiency).

To illustrate the design method of the present invention, an exemplary design will be described. The exemplary design goal is a floor-standing loud speaker enclosure that benefits from the invention. To determine the appropriate mechanical construction of the enclosure, the starting point is the selection of the diameter of the driver to be used.

For Example: the Driver selected is a nominal 5 inch diameter driver with an “effective diameter” or diaphragm diameter of 4.5 inches. (The effective diameter is the diameter of the cone or diaphragm within the surround).
Therefore, the Area A_{DC}=πr²=3.1416×2.25²=16 square inches (in²)

The second primary consideration is to select the transmission line length.

In accordance with the method of the present invention, the transmission line length or path length needs to be greater than 2.5 times the effective driver cone diameter (2.5×4.5 inches), but is preferably or optimally equal to or greater than 3 times the effective driver cone diameter (3×4.5 inches)−>13.5 inches.

In order to hear the sound at a convenient height above the floor, the length of the transmission line was selected to be 36 inches (which satisfies the criteria of >13.5 inches).

Adapting a conventional rectangular box for the enclosure, the interior width of the box was selected to be 6 inches (to meet the mounting requirements of the driver, which happens to require a 5 inch diameter hole in the front baffle).

To determine the interior depth, consideration must be given to the criteria that the cross-sectional area of the transmission path directly behind the driver should fall within 0.707 and 1.414 times the effective cross-sectional area of the driver cone A_{DC}.

So, preferably, the cross-sectional area of transmission line path behind speaker is selected to be between 11.312 in² and 22.624 in².

In the design of the instant example, 3 inches was selected for the internal enclosure depth (giving an area of 6 inches×3 inches=18 in²) which meets the criteria. After consideration for materials used in the construction and assembly methods this was, for convenience, reduced to 2⅞ inches which still meets the criteria. (17.25 in²).

In order to divert the driver's back pressure wave away from the driver and down the transmission line path, a miter baffle is required. From experience, this must be angled somewhere between 45 degrees and 60 degrees with respect to the central axis of the driver cone. In this example, a 55 degree angle was selected, with a baffle length of 2⅝ inches to avoid interference with the driver magnet during assembly.

To check the efficiency of acoustical power transfer, the ratio of the cross-sectional area along the transmission line path directly behind the driver to the effective driver cone area (A_{DC}) is determined:

That ratio is, for this example, 17.25/16=1.08. This ratio falls well within the requirements of the method of the present invention. This is true for the upper 8 inches of the transmission line path in the tapered cabinet of the exemplary embodiment.

With the driver's back wave sound heading down towards the proposed port, the port dimension needs to be determined such that the area of the port lies between 0.707 and 1.414 times the effective cross-sectional area of the driver cone, A_{DC}.
So, 11.312 in²<Cross-sectional area of the port<22.624 in²

Since the area of the driver is 16 in² and the depth of the box is 2⅞ inches, the height of the port calculates to 5.5 inches to give an approximate 1 to 1 ratio of port area to driver cone area, which falls within the mid range of allowable area.

For convenience and aesthetic considerations the height of the port was selected to be 5 inches, and so:
5×2.875=14.375 in²
which still falls within the required area parameters for acoustic impedance.

To assure efficient transfer of power from the driver to the port, the ratio is determined.
Area of Port/Area of driver=14.375/16=0.898
again which meets the criteria for Power Transfer efficiency.

Any abrupt change in Acoustical Impedance along the transmission line path would cause reflection of the driver's back pressure wave and a corresponding standing wave resonance within the transmission line path, and so, to minimize a standing wave condition, there should be no abrupt change in the cross-sectional area of the transmission line path at any point along the transmission line path length.

In this example, the cross-sectional area is preferably gradually reduced from 17.25 in² down to 14.375 in². This segment of the transmission line path behaves, effectively, like an acoustic transformer or impedance matching network.

The inventors chose to keep the depth of the enclosure constant, therefore the sides of the box preferably to taper symmetrically inwards at approx 2.5 degrees from vertical to accomplish the required gradual and progressive reduction in transmission line cross-sectional area.

Since, at low frequencies, it is preferably desired that the air move in a laminar flow which requires an angle of about 5 degrees or less to assure high efficiency and avoid turbulent loss, having the box side walls taper inwardly at 2.5 degrees from vertical meets this criteria.

At the termination or port end of the acoustic transformer portion of the transmission line, the cross-sectional area is 11.73 sq in, which falls within the parameters.

Preferably, the transmission line path includes, near the port end, a deflector miter or reflective wall surface angled at 45 degrees to reflect the sound in the transmission line out through the port. The sound travels in a direction that is preferably orthogonal to the driver's front wave or at least 90 degrees from the axis of the driver's front wave.

Optionally, the transmission port path may be measured to determine that there is an acceptably low level of standing wave resonance. If a standing wave resonance having an unacceptably high amplitude is detected, the anti-node locations can be found for selected frequencies, and one or more small apertures or vent holes (e.g., three eighth inch diameter) can be provided to vent the air column's anti-node pressure peaks to the outside atmosphere; such small vent holes are referred to as nodal vents. At sound frequencies of interest, the nodal vents pass essentially no air and contribute negligible losses at frequencies other than the selected frequency of interest.

The above and still further objects, features and advantages of the present invention will become apparent upon consideration of the following detailed description of specific embodiments thereof, particularly when taken in conjunction with the accompanying Figures, wherein like reference numerals in the various figures are utilized to designate like components.

### BRIEF DESCRIPTION OF THE DRAWINGS

FIG. 1 is a partial cross sectional view, in perspective, of a loudspeaker enclosure having an acoustic impedance matched transmission line path, in accordance with a preferred embodiment of the present invention.

FIG. 2 is a front partial cross sectional view, in elevation, of the loudspeaker enclosure with acoustic impedance matched transmission line path of FIG. 1, in accordance with a preferred embodiment of the present invention.

FIG. 3 is a side partial cross sectional view, in elevation, of the loudspeaker enclosure of FIGS. 1 and 2, in accordance with a preferred embodiment of the present invention.

### DETAILED DESCRIPTION OF THE PREFERRED EMBODIMENTS

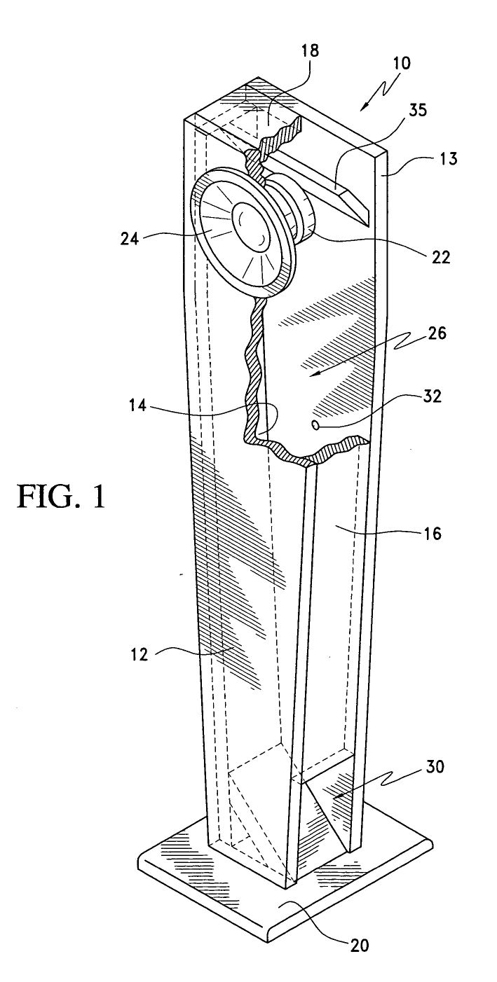

With reference to FIGS. 1, 2 and 3, a loudspeaker enclosure 10 includes a substantially planar front baffle 12 joined at opposing sides in intersections or joints to sealably engage opposing substantially planar first and second side walls, 14, 16. Front baffle 12 is terminated at its top edge with enclosure top end wall 18 and at its bottom edge with enclosure bottom wall or plinth 20, to sealably engage in intersections or joints. A substantially planar rear wall 13 is supported in a substantially parallel relationship with front baffle 12. Rear wall 13 is joined at opposing sides in intersections or joints to sealably engage first and second side walls, 14, 16. Rear wall 13 is terminated at its top edge with enclosure top end wall 18 and at its bottom edge with enclosure bottom wall or plinth 20, to sealably engage in intersections or joints, to define an enclosure interior volume 26 containing a column of air.

In the preferred embodiment, front baffle 12, first side wall 14, second side wall 16, top end wall 18, bottom wall or plinth 20 and rear wall 13 are all fabricated from a gas-impermeable, non-resonant building material such as half inch thick sheets of medium density fiberboard (MDF). The joints or intersections are preferably bonded with a suitable adhesive and may include one or more fasteners such as threaded wood screws or the like, to provide a substantially gas-tight seal at each joint.

Enclosure front baffle 10 includes a substantially circular aperture sized to receive the basket flange of a loudspeaker driver 22 with loudspeaker driver cone or diaphragm 24 facing forwardly such that when excited, driver 22 will generate a front wave that propagates forwardly into a hemisphere bisected by the plane of front baffle 12, and will generate a back pressure wave that is radiated into the enclosure interior volume 26, to pressurize the column of air in the enclosure.

Advantageously, the enclosure interior volume 26 of enclosure 10 is configured with an acoustic impedance matched transmission line path 28 terminating distally in port 30 at the bottom of second sidewall 16. An optional nodal vent hole 32 may be placed at a selected location in a side wall, rear wall 13 (as shown) of front baffle 12, as will described in greater detail below.

In the embodiment illustrated, the enclosure's acoustic impedance matched transmission line path 28 has an inlet or proximal end adjacent an angled reflector 35 oriented at a selected angle 40 (e.g., 55 degrees from horizontal) and terminates at an outlet or distal end including a second angled reflector or outboard reflector 50 oriented at a selected angle 52 (e.g., 45 degrees from horizontal) to direct acoustic energy to port 30.

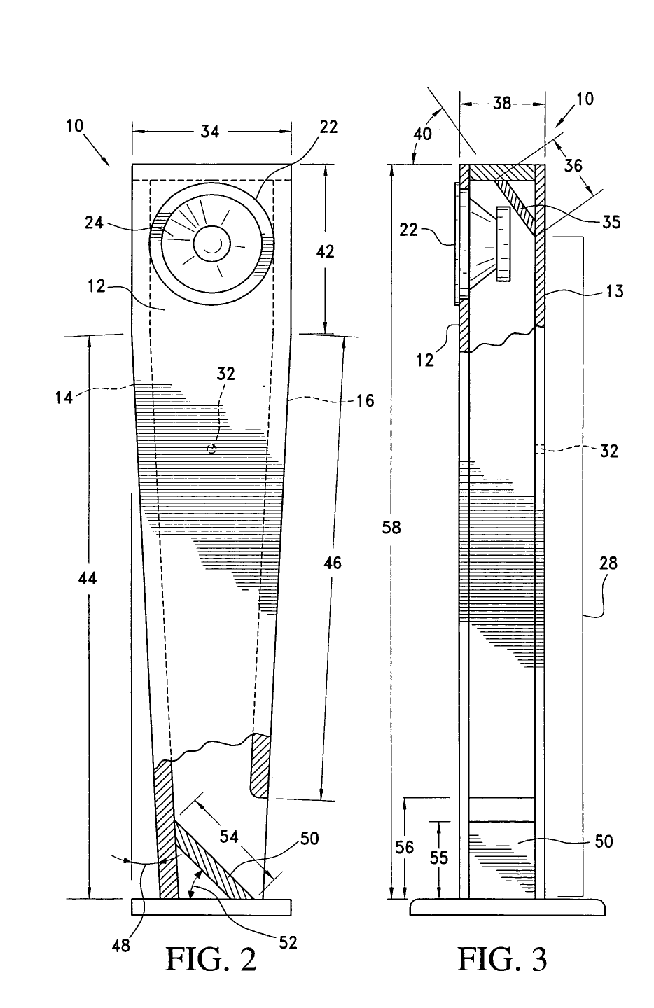

In the embodiment illustrated, the enclosure or cabinet's top width 34 is preferably approximately seven and one half inches. As best seen in FIG. 2, vertical side wall segments have a vertical height 42, preferably approximately eight inches and terminate in angled side wall segments angled inwardly at a selected side wall taper angle 48, (e.g., 2.5 degrees from vertical), to define the impedance matching portion of acoustic impedance matched transmission line path 28, which preferably has a height 44 of approximately 28.125 inches. Side wall 16 has a tapered segment height 46 of approximately 23.125 inches, terminating at its bottom edge in port 30 which has a height 56 of approximately 5 inches. Enclosure 10 has a depth 38 of approximately 3.875 inches, and so the width of port 30 is preferably 2.875 inches.

The driver 's back wave communicates through a passage adapted to function as an impedance-matched transmission line cavity having a length 28 that is, preferably three times the diameter of driver cone 24, and having one or more ports 30 terminating in openings defined in a plane that is, preferably, substantially perpendicular to the enclosure's planar front. The port or ports have a cross sectional area of 0.5 to about 2.0 times the operative area of the driver cone 24 of the loudspeaker (preferably 0.707 to 1.414 times the operative area of the driver cone), thereby giving a highly efficient means of sound propagation.

Enclosure 10 may also support optional high frequency “tweeter” speakers (not shown), which provide one or more planes of sound propagation depending on the usage environment. The architecture of the internal speaker box design provides reflectors or deflectors 35, 50 to provide the most direct path of sound egress and minimize resonant standing waves or sound cancellation effects associated with the opposite polarity of the back acoustic waves derived from the speaker 22. The resultant transmission path 28 and port opening 30 for the back acoustic waves minimizes acoustic cancellation between the front and back acoustic waves while simultaneously facilitating the maximum possible propagation of acoustic energy derived from the speaker 22 by virtue of the matching to the characteristic acoustic impedance of the driver 22 at the port(s).

In accordance with the method of the present invention, the acoustical characteristic impedance of driver 22 is “matched” to the acoustical impedance of the enclosure 10 such that enclosure 10 does not resonate, and provides maximum sound propagation. To further allow energy to transfer efficiently and in order for the acoustic back wave to not cancel any of the front wave, the back wave propagates at greater than 90 degrees from the vector angle of the front wave propagation. In order to provide some physical understanding of this process of “matching”, it is noted that:
Sound Intensity/=is defined as p²/ρc, (1)
where p=Sound Pressure Level (SPL),
and where Acoustical Characteristic Impedance ρc
and where ρ=density of Air (g/cm³),
c=constant velocity for sound (cm/sec)

Equation 1 gives the dimensional units of Acoustical Characteristic Impedance, ρc, as: (g/cm²)(sec).

When examining Acoustical Impedance, the mass (g) is ever present for the medium (Air) that the sound is propagating within. So, within enclosure 10, the variable available to the designer is “Area”, since sound moves at a constant velocity. “Area”, as used in the method of the present invention, is the cross sectional area of the transmission line path 28 that the driver's back wave or pressure wave travels along to exit enclosure 10.

From a hypothetical Electrical Power application which can be analogously applied to acoustic power application, one can follow the rule that the most efficient (maximum) transfer of power occurs within the limits of √2 and 1/√2, meaning that when a first network's impedance is a multiple of between √2 and 1/√2 times a second network's impedance, then the impedances are deemed to be matched, and so signal reflections and standing waves are likely to be acceptably low.

In the method of the present invention, Area is determined to be the variable, and so for the most efficient transfer of acoustical power, the area of transmission line 28 should at all times fall within √2×Cross-sectional area of driver cone 24 and 1/√2×Cross-sectional Area of diver cone. 24, i.e. Between 0.707A_{DC} and 1.414A_{DC}, where A_{DC}=Effective cross-sectional area of driver cone 24.

In order for driver 22 to recognize its characteristic impedance within enclosure 10, the length of the transmission line path must be sufficient. This has been empirically determined by the inventors to be equal to or greater than 2.5 times to 3 times the active diameter of the driver cone 24 (with 2.5 times the driver cone diameter giving the minimum acceptable efficiency).

To illustrate the design method of the present invention, an exemplary design will be described. The exemplary design goal is a floor-standing loud speaker enclosure 10 that benefits from the invention. To determine the appropriate mechanical construction of the enclosure, the starting point is the selection of the diameter of the driver to be used.

In the exemplary embodiment of FIGS. 1-3, a five inch (nominal) Peerless™ brand mid-bass driver, model 850489, is selected as driver 22. Driver 22 has an “effective diameter” or diaphragm diameter of 4.5 inches. (The effective diameter is the diameter of cone or diaphragm 24 within the surround).
Therefore, the Area A_{DC}=πr²=3.1416×2.25²=16 square inches (in²)

The second primary consideration is to select the transmission line length.

In accordance with the method of the present invention, the transmission line length 28 or path length needs to be greater than 2.5 times the effective driver cone diameter (2.5×4.5 inches), but is preferably or optimally equal to or greater than 3 times the effective driver cone diameter (3×4.5 inches)−>13.5 inches.

In order to hear the sound at a convenient height above the floor, the length of the transmission line (i.e., tapered length 44 plus top side wall length 42) was selected to be 36 inches (which satisfies the criteria of >13.5 inches).

Adapting from a conventional rectangular box to develop enclosure 10, the interior volume width of the box was selected to be 6 inches (to meet the mounting requirements of the driver, which happens to require a 5 inch diameter hole in front baffle 12).

To determine the interior depth, consideration must be given to the criteria that the cross-sectional area of the transmission path directly behind the driver should fall within 0.707 and 1.414 times the effective cross-sectional area of the driver cone A_{DC}.

So, preferably, the cross-sectional area of transmission line path behind speaker 22 is selected to be between 11.312 in² and 22.624 in².

In the design of the instant example, 3 inches was selected for the internal enclosure depth (giving an area of 6 inches×3 inches=18 in²) which meets the criteria. After consideration for materials used in the construction and assembly methods this was, for convenience, reduced to 2⅞ inches which still meets the criteria. (17.25 in²).

In order to divert the driver's back pressure wave away from driver 22 and down the transmission line path 28, a miter baffle 35 is required. From experience, this must be angled somewhere between 45 degrees and 60 degrees with respect to the central axis of the driver cone 24. In this example, a 55 degree angle was selected, with a baffle length 36 of 2⅝ inches to avoid interference with the driver magnet, during assembly.

To check the efficiency of acoustical power transfer, the ratio of the cross-sectional area along the transmission line path 28, directly behind driver 22 to the effective driver cone area (A_{DC}) is determined:

That ratio is, for this example, 17.25/16=1.08. This ratio falls well within the requirements of the method of the present invention. This is true for the upper 8 inches of the transmission line path in the tapered cabinet of the exemplary embodiment.

With the driver's back wave sound heading down towards port 30, the port dimension needs to be determined such that the area of the port lies between 0.707 and 1.414 times the effective cross-sectional area of the driver cone 24, A_{DC}.
So, 11.312 in²<Cross-sectional area of the port<22.624 in²

Since the area of the driver is 16 in² and the depth of the box is 2⅞ inches, the height of the port calculates to 5.5 inches to give an approximate 1 to 1 ratio of port area to driver cone area, which falls within the mid range of allowable area.

For convenience and aesthetic considerations the height of port 30 was selected to be 5 inches, and so:
5×2.875=14.375 in²
which still falls within the required area parameters for acoustic impedance.

To assure efficient transfer of power from the driver 22 to port 30, the ratio is determined.
Area of Port/Area of driver=14.375/16=0.898
again which meets the criteria for Power Transfer efficiency, in accordance with the method of the present invention.

Any abrupt change in Acoustical Impedance along the air column in transmission line path would cause reflection of the driver's back pressure wave and a corresponding standing wave resonance within the transmission line path, and so, to minimize a standing wave condition, there should be no abrupt change in the cross-sectional area of the transmission line path at any point along the transmission line path length 28.

In this example, the cross-sectional area is preferably gradually reduced from 17.25 in² down to 14.375 in². This segment of the transmission line path behaves, effectively, like an acoustic transformer or impedance matching network having a vertical extent 44.

The inventors chose to keep the depth of the enclosure constant, therefore the sides of the box preferably to taper symmetrically inwards at a selected angle 48, (e.g., approx 2.5 degrees from vertical) to accomplish the required gradual and progressive reduction in transmission line cross-sectional area.

Since, at low frequencies, it is preferably desired that the air move in a laminar flow which requires an angle of about 5 degrees or less to assure high efficiency and avoid turbulent loss, having the box side walls taper inwardly at 2.5 degrees from vertical meets this criteria.

At the termination or port end of the acoustic transformer portion of the transmission line, the cross-sectional area is 11.73 sq in, which falls within the parameters.

Preferably, the transmission line path 28 includes, near the port end, a deflector miter or reflective wall surface 50 angled at a selected angle 52 (e.g., 45 degrees) to reflect the sound in the transmission line out through port 30. The sound travels in a direction that is preferably orthogonal to the driver's front wave or at least 90 degrees from the axis of the driver's front wave.

Optionally, the transmission line path 28 may be measured to determine that there is an acceptably low level of standing wave resonance. If a standing wave resonance having an unacceptably high amplitude is detected, the anti-node locations can be found for selected frequencies, and one or more small apertures or vent holes 32 of, preferably, less than one inch diameter, (e.g., three eighth inch diameter) can be provided to vent the air column's anti-node pressure peaks to the outside atmosphere; such small vent holes are referred to as nodal vents 32. At sound frequencies of interest, nodal vents 32 pass essentially no air and contribute negligible losses at frequencies other than the selected frequency of interest.

In an alternative embodiment of the invention, enclosure 10 can be configured as an “in-wall” speaker cabinet. In this example, the speaker cabinet is divided into 2 parts as a double woofer cabinet with two ports, and a mid-range/tweeter component (not shown). Each woofer part comprising an isolated and enclosed enclosure with its own single port. The speaker driver selected for both parts have a 6.5 inch diameter cone. The depth and the width of the cabinet is configured to approximately equal the cone diameter, but in any case need to be within about √2 [1.414 times that] of the cone diameter so that the resultant cross-sectional area of the transmission path is close to the √2 of the cross sectional area of the cone driver.

Note:
Enclosed circle area of unity diameter=(½)²=¼=0.7854
Enclosing square area=1×1=1
Therefore, ratio=1/(0.7854)=1.273≅1.27, <1.4 is ideal.
The acoustic length of the transmission line is designed and configured to be equal The transmission path length is preferably up to or in excess of three times the diameter of the driver cone to establish sufficient length to provide a matching acoustic impedance as seen or sensed by the driver. One or more reflectors are sized and positioned so as to reflect the rearwardly directed (“back”) acoustic energy away from the rear of the driver cone and along the transmission line towards and ultimately through the port. The port dimensions are sized to give an area between 1.414 times the driver cone area (1.414×Cone Area) and 1/(1.414) times the driver cone area (0.707×Cone Area) and preferably approaching (0.707×Cone Area), in order to provide a damping acoustic load at the port with maximized balanced free flow of the back acoustic sound waves. The square root of two is 1.414 and its reciprocal corresponds to the impedance range, when rounded, and that is the value range used in these computations for maximum power transfer as in electrical theory as well. In this example, the 6.5 inch driver gives a Cone Area of 33.2 square inches. Using the method of the present invention, the best minimum port dimensions yield a resultant port area of >0.707×33.2=>23.47 square inches. The port dimensions are selected to be 6″×4″, giving an area of 24 square inches.

Another embodiment of the invention in the form of a free standing home speaker cabinet houses four 8 inch drivers each contained within their own individual and isolated transmission line enclosures (not shown). These are stacked vertically in a line array. The speaker driver selected for all four drivers have an 8 inch diameter cone. The depth and the width of the cabinet is configured to approach the cone area as much as possible, but in any case needs to be within √2 of the cone diameter so that the resultant cross-sectional area of the transmission path is close to the cross sectional area of the cone driver. The length of the transmission line is configured to be equal or in excess of three times the diameter of the driver cone to establish a matching of the impedance of the air within the speaker cabinet transmission line to the impedance of the driver cone in air. In this example no physical reflectors are used since the transmission line follows the natural flow of the back acoustic waves being ported directly 180 degrees opposite to the front acoustic waves. The port dimensions are sized to give an area between 1.414 times the driver cone area (1.414×Cone Area) and 1/(1.414) times the driver cone area (0.707×Cone Area) in order to maximize balanced free flow of the back acoustic sound waves. In this example the 8 inch driver gives a Cone Area of 50 square inches. The minimum port dimensions yield a resultant port area of >0.707×50=>35.35 square inches. The port dimensions are selected to be 7″×8.5″, giving an area of 59.5 square inches. The port aperture is angled at 22.5 degrees to deflect the back sound waves and avoid acoustic “slap back” in small rooms. The transmission line is further arranged to provide an acoustic transformer function to increase the output sound pressure at the port and provide nominal acoustic loading. The port orientation is sized and configured to act as an acoustic deflector to the egressing back sound waves. The acoustic transformer action is accomplished by a narrowing and reduction of the transmission path area to approximately 94% of the rectangle surrounding the driver cone area thus providing a degree of back sound wave compression. Each cabinet section incorporates a nodal vent hole positioned halfway along, and central within the transmission path and on the opposite cabinet wall to the port exit to prevent the slight natural “pipe response” of the enclosure from being perceived. The vent holes are sized to prevent resonant pressure build up exhibited by no air flow out of the vent (node) and excessive out flow of back sound waves through the vent hole giving the effect of flattening the mid-base frequencies. Tweeters are included on a separate flange to provide high frequency response.

Yet another embodiment of the invention in the form of a free standing lay-down lateral commercial low frequency speaker cabinet houses one 15 inch and one 18 inch driver, each contained within their own individual and isolated sub-enclosures (not shown). These are stacked vertically in a line array. When used together, the drivers are preferably aligned vertically. The height and width of each cabinet section is configured to be approximately equal to the cone diameter. The length of the transmission line is designed and configured to be equal or in excess of three times the diameter of the driver cone to establish a matching of the impedance of the air within the speaker cabinet transmission line to the impedance of the driver cone in air. In this example physical reflectors are used to reflect the back sound waves out of the port at an angle of 90 degrees perpendicular to the driver front acoustic wave path. The port dimensions are sized to give an area between 1.414 times the driver cone area (1.414×Cone Area) and 1/(1.414) times the driver cone area (0.707×Cone Area) in order to best match the back acoustic sound waves. In this example, the 18 inch driver gives a Cone Area of 254 square inches. The minimum port dimensions yield a resultant port area of >0.707×254=>180 square inches. The port dimensions are selected to be 12″×18.25″ giving an area of 219 square inches. The port is angled at 90 degrees to the front sound waves. The transmission line is further arranged to provide an acoustic transformer function to increase the output sound pressure at the port thus adding acoustic loading to the matched impedance load to the driver. The port orientation is sized and configured to act as an acoustic reflector to deflect the back sound waves (opposite polarity) to efficiently couple the entire sound wave into space. The acoustic transformer action is accomplished by gradually narrowing of the transmission path area. Each cabinet section incorporates a nodal vent hole positioned halfway along, and central within is the transmission path and on the opposite cabinet wall to the port exit to smooth the response within about 1 Db about the natural response mode usually exhibiting less than 3 Db rise with good matched impedance loading. The vent holes are sized empirically at about 1/2 inch diameter to provide a node at the natural antinode with minimal pressure loss at all frequencies.

Another exemplary embodiment of the invention in the form of a free standing vertical commercial high power wide band speaker cabinet houses one 15 inch driver and four external tweeters (not shown). The depth and the width of the cabinet at the driver is configured to tightly contain the cone diameter, the resultant cross-sectional area of the transmission path is approximately equal to 1.4 of the cross sectional area of the cone driver. The length of the transmission line is designed and configured to be equal or in excess of three times of the diameter of the driver cone to establish a matching of its characteristic acoustic impedance. In this example physical reflectors are used to divide and reflect the back sound waves of the transmission path out of the two ports, each at an angle of 90 degrees perpendicular to the driver front acoustic wave path. The angle of each reflector needs to be at 45 degrees. The dividing member must extend well above the port lip internally. Each port area is half of that used for single port. In this example the 15 inch driver gives a Cone Area of 176 square inches. The minimum single port dimensions yield a resultant port area of >0.5×176=>88 square inches. The port dimensions are selected to be 3″×16″ with 2 ports giving a total port area of 96 square inches. The ports are angled at 90 degrees to either side of the plane of the front sound waves. The transmission line is further arranged to provide an acoustic transformer function to optimally match the driver impedance to the port(s). There is, preferably, no nodal vent in the cabinet.

It will be appreciated by those of skill in the art that the enclosure (e.g., 10) and method of the present invention provides, generally, a loudspeaker enclosure comprising a box having external front, rear and lateral side walls, and external top and bottom walls, an opening in one of said forward facing external walls for placing a loudspeaker (e.g., 22) which provides both front and back acoustic waves of bass and/or mid-range audio frequencies; a port in a second external wall disposed to be substantially perpendicular or opposite to the opening in said front wall, the port being arranged for association with the side of the enclosure wall which is perpendicular to the said front side and having a cross sectional area from about 0.5 to about 2.0 times the operative area of a loudspeaker associated therewith, such that the sound propagation vector angles between the front and back acoustic waves are disposed at greater than 90 degrees when considered in a 3-Dimensional plane; and the interior of the box between the wall opening and the port being proportioned and arranged to function as an acoustic transmission line which is terminated in the port, frequently employing tapered sides to gradually match the associated “character impedance” areas with an acoustic transformer action.

The loudspeaker enclosure may have two ports with two associated acoustic transmission lines terminating in the two separate ports, both ports being orientated substantially perpendicular to said one side of the loudspeaker, where the sum of the cross sectional areas of the ports equates to about 0.5 to about 2.0 times the operative area of a loudspeaker to be associated therewith, and the sound propagation vector angles between the front and each of the back acoustic waves are disposed at greater than 90 degrees when considered in a 3-Dimensional plane. Optionally, a lip (not shown) surrounding at least part of the port produces turbulent flow through the port and may be associated with an adjacent back plate support to forwardly direct the egressing wave with diminishing acoustic pressure.

The loudspeaker enclosure may include one or more additional sealed openings in one or more walls of the enclosure for association with one or more electromagnetic tweeter loudspeakers (not shown) providing acoustic waves of high audio frequencies. The loudspeaker enclosure may include a mid-positioned nodal vent dampening arrangement within the enclosure that is selectively sized and dimensioned to achieve substantially no passage of air upon operation of the transmission line at its fundamental resonance at an antinode in the air column formed by the enclosure, while contributing negligible loss at other frequencies.

In conclusion, the present invention comprises a new approach to designing a loudspeaker enclosure 10 to optimally cooperate with at least one electromagnetic loudspeaker driver 22 generating both front and back acoustic waves. The driver 's back wave communicates through passage adapted to function as a transmission line cavity having one or more ports 30 terminating in openings defined in a plane that is substantially perpendicular or opposite to the planar front. The port(s) is provided with a cross sectional area of from about 0.5 to about 2.0 times the operative area of the driver cone 24, thereby giving a highly efficient means of sound propagation. The enclosure may also house high frequency “tweeter” speakers (not shown) which provide one or more planes of sound propagation depending on the usage environment. The architecture of the internal speaker box design provides various reflectors 35, 50 to provide the most direct path of sound egress and minimize standing waves or sound cancellation effects associated with the back acoustic waves derived from driver 22. The resultant transmission path 28 and port opening 30 for the back acoustic waves minimizes acoustic cancellation between the front and back acoustic waves while simultaneously facilitating the maximum possible propagation of acoustic energy derived from the speaker by virtue of matching the characteristic acoustic impedance of the driver at its port(s).

Although the invention has been disclosed in terms of a number of preferred embodiment and numerous variations thereon, it will be understood that numerous additional modifications and variations could be made thereto without departing from the scope of the invention as defined in the following claims.

1. A loudspeaker enclosure adapted to support an electromechanical transducer or loudspeaker driver comprising, in combination:
(a) a hollow enclosure having front and rear walls intersected by first and second opposing side walls and first and second end walls joined at said intersections to define an enclosed volume,
(b) a first loudspeaker driver having a selected diaphragm diameter, a selected diaphragm surface area and an acoustic characteristic impedance and mounted on a selected one of said walls of said hollow enclosure in an opening sized to receive one side of said first loudspeaker driver, said wall being designated as a driver mounting baffle;
(c) said loudspeaker driver being configured to receive an electrical excitation signal and, in response, providing both front and back acoustic waves of audio frequencies, wherein said front acoustic wave is radiated outwardly into free space and said back acoustic wave is radiated inwardly into said enclosed volume;
(d) a port of a predetermined cross sectional area located in a wall opposing said driver mounting baffle, said port being in fluid communication with a transmission line path having a selected length and a selected cross sectional area over most of said length;
(e) said transmission line path having an inlet end proximate said first loudspeaker driver and configured to receive substantially all of said back acoustic wave, and having an outlet end defined by said port;
(f) said transmission line length being greater than two and one half times said first loudspeaker driver diaphragm's diameter; and
(g) wherein said transmission line path is dimensioned to provide an acoustic characteristic impedance that substantially equals said first loudspeaker driver's acoustic characteristic impedance.

2. The loudspeaker enclosure of claim 1, wherein said transmission line path's acoustic characteristic impedance is determined substantially by said port cross sectional area, and
wherein the cross sectional area of said port equals an area that is greater than said first loudspeaker driver's diaphragm surface area multiplied by 0.707 and less than said first loudspeaker driver's diaphragm surface area multiplied by 1.414.

3. The loudspeaker enclosure of claim 1, wherein said transmission line path inlet is configured with an angled reflective surface to direct substantially all of said back acoustic wave into an orthogonal direction with respect to said driver diaphragm.

4. The loudspeaker enclosure of claim 3, wherein said transmission line path outlet is configured with an angled reflective surface to direct substantially all of said back acoustic wave to said port.

5. The loudspeaker enclosure of claim 1, wherein at least one of said enclosure baffle or enclosure walls includes a small nodal vent hole having a diameter of less than one inch and placed to neutralize excessive anti-node pressure amplitudes in air enclosed in said transmission line path.

6. The loudspeaker enclosure of claim 5, wherein said nodal vent hole diameter is three-eighths inch diameter.

7. The loudspeaker enclosure of claim, wherein said driver comprises a five inch nominal loudspeaker driver having an effective driver diaphragm area of approximately 16 square inches.

8. The loudspeaker enclosure of claim 7, wherein said transmission line cross sectional area is between 11 inches and 23 inches.

9. The loudspeaker enclosure of claim 7, wherein said transmission line cross sectional area is greater than 12.5 inches.

10. A loudspeaker enclosure adapted to support an electromechanical transducer or loudspeaker driver comprising, in combination:
(a) a hollow enclosure having a substantially planar front wall segment intersected by one or more side walls joined to define an enclosed volume,
(b) a first loudspeaker driver having a selected diaphragm diameter, a selected diaphragm surface area and a characteristic impedance and mounted on said front walls of said hollow enclosure in an opening sized to receive one side of said first loudspeaker driver;
(c) said loudspeaker driver being configured to receive an electrical excitation signal and, in response, providing both front and back acoustic waves of audio frequencies, wherein said front acoustic wave is radiated outwardly into free space and said back acoustic wave is radiated inwardly into said enclosed volume; (d) a port of a predetermined cross sectional area located in a wall segment offset by at least ninety degrees from said planar front wall segment, said port being in fluid communication with a transmission line path having a selected length and a selected cross sectional area over most of said length;
(e) said transmission line path having an inlet proximate said first loudspeaker driver and configured with an angled reflective surface to direct substantially all of said back acoustic wave into an orthogonal direction with respect to said driver diaphragm, and having an outlet end defined by said port;
(f) said transmission line length being greater than two and one half times said first loudspeaker driver diaphragm's diameter;
(g) wherein the cross sectional area of said port equals an area that is greater than said first loudspeaker driver's diaphragm surface area multiplied by 0.707; and
(h) wherein the cross sectional area of said port equals an area that is less than said first loudspeaker driver's diaphragm surface area multiplied by 1.414.

11. The loudspeaker enclosure of claim 10, wherein said transmission line path includes an acoustic characteristic impedance matching segment between said transmission line path inlet and said port.

12. The loudspeaker enclosure of claim 11, wherein said transmission line path acoustic characteristic impedance matching segment comprises at least one tapered wall segment between said transmission line path inlet and said port.

13. The loudspeaker enclosure of claim 12, wherein said acoustic characteristic impedance matching segment tapered wall segment tapers at less than an angle of five degrees, to avoid turbulence in an air column in said acoustic characteristic impedance matching segment.

14. The loudspeaker enclosure of claim 13, wherein said acoustic characteristic impedance matching segment tapered wall segment tapers at an angle of 2.5 degrees.

15. The loudspeaker enclosure of claim 11, wherein at least one of said enclosure walls includes a small nodal vent hole having a diameter of less than one inch and placed to neutralize excessive anti-node pressure amplitudes in air enclosed in said transmission line path.

16. The loudspeaker enclosure of claim 11, wherein said transmission line path outlet is configured with an angled reflective surface to direct substantially all of said back acoustic wave to said port.

17. A method of optimizing the transmission of acoustic energy from a loudspeaker driver through an enclosure interior volume into free space without exciting standing waves of excessive amplitude in the loudspeaker enclosure comprising the steps of:
(a) providing a loudspeaker driver having a selected diameter and a effective diaphragm area;
(b) providing a substantially sealed transmission line path adapted to enclose a column of air, said transmission line path having a length selected to be at least two and one half times the diameter of said driver;
(c) providing said transmission line path with a cross sectional area selected to be at least 0.707 times the effective diaphragm area of said driver and less than 1.414 times the effective diaphragm area of said driver; and
(d) sealably mounting said driver at the inlet end of a transmission line path adapted to receive said driver's back wave.

18. The method of claim 17, further comprising the step of:
(e) detecting whether, during playback at a selected audio frequency, the air column in the transmission line exhibits excessive standing wave anti-node pressure amplitude, and, if so, identifying a nodal vent location on a selected enclosure wall surface.

19. The method of claim 18, further comprising the step of:
(f) making an aperture in said selected enclosure wall surface proximate the location of said air column's excessive standing wave anti-node pressure amplitude.

20. The method of claim 19, further comprising the step of:
(g) detecting whether, during playback at the selected audio frequency, the air column in the transmission line still exhibits excessive standing wave anti-node pressure amplitude proximate said nodal vent location.
